(19) United States
(12) Patent Application Publication
(10) Pub. No.: US 2025/0095695 A1
(43) Pub. Date: Mar. 20, 2025

(54) MAGNETIC MEMORY DEVICE

(71) Applicant: Kioxia Corporation, Tokyo (JP)

(72) Inventor: Yuichi ITO, Seoul (KR)

(73) Assignee: Kioxia Corporation, Tokyo (JP)

(21) Appl. No.: 18/884,013

(22) Filed: Sep. 12, 2024

(30) Foreign Application Priority Data
Sep. 19, 2023 (JP) 2023-150934

(51) Int. Cl. G11C 5/08; H10B 61/00; H10N 50/10

(52) U.S. Cl. CPC G11C 5/08; H10B 61/10; H10N 50/10

(57) ABSTRACT

According to one embodiment, a magnetic memory device includes a first wiring line extending along a first direction, a second wiring line provided on an upper layer side of the first wiring line and extending along a second direction, a memory cell provided between the first wiring line and the second wiring line, including a bottom surface connected to the first wiring line and a top surface connected to the second wiring line, and including a magnetoresistance effect element and a switching element stacked in a third direction, and a contact including a top surface connected to the second wiring line, the top surface of the contact being located higher than the top surface of the memory cell.

### CROSS-REFERENCE TO RELATED APPLICATIONS

This application is based upon and claims the benefit of priority from Japanese Patent Application No. 2023-150934, filed Sep. 19, 2023, the entire contents of which are incorporated herein by reference.

### FIELD

Embodiments described herein relate generally to a magnetic memory device.

### BACKGROUND

A magnetic memory device has been proposed in which a plurality of memory cells each including a magnetoresistance effect element and a selector (switching element) are integrated on a semiconductor substrate.

### BRIEF DESCRIPTION OF THE DRAWINGS

FIG. 1 is a planar pattern diagram schematically showing a configuration of a magnetic memory device according to a first embodiment as viewed from a Z direction.

FIG. 2 is a cross-sectional view perpendicular to an X direction, schematically showing the configuration of the magnetic memory device according to the first embodiment.

FIG. 3 is a cross-sectional view perpendicular to a Y direction, schematically showing the configuration of the magnetic memory device according to the first embodiment.

FIG. 4 is a cross-sectional view perpendicular to a Y direction, schematically showing the configuration of the magnetic memory device according to the first embodiment.

FIG. 5 is a cross-sectional view schematically showing a basic configuration of a magnetoresistance effect element of the magnetic memory device of the first embodiment.

FIGS. 6A and 6B, FIGS. 7A and 7B, and

FIGS. 8A and 8B are cross-sectional views schematically showing a method of manufacturing the magnetic memory device according to the first embodiment.

FIG. 9 is a planar pattern diagram, schematically showing a configuration of a magnetic memory device according to a second embodiment as viewed from the Z direction.

FIG. 10 is a cross-sectional view perpendicular to the X direction, schematically showing the configuration of the magnetic memory device according to the second embodiment.

FIG. 11 is a cross-sectional view perpendicular to the Y direction, schematically showing the configuration of the magnetic memory device according to the second embodiment.

FIG. 12 is a cross-sectional view perpendicular to the Y direction, schematically showing the configuration of the magnetic memory device according to the second embodiment.

FIGS. 13A and 13B, FIGS. 14A and 14B, FIGS. 15A and 15B, FIGS. 16A and 16B, FIGS. 17A and 17B, and FIGS. 18A and 18B are cross-sectional views schematically showing a method of manufacturing the magnetic memory device according to the second embodiment.

FIG. 19 is a cross-sectional view perpendicular to the Y direction, schematically showing a configuration of a magnetic memory device according to a third embodiment.

FIG. 20 is a cross-sectional view perpendicular to the Y direction, schematically showing the configuration of the magnetic memory device according to the third embodiment.

FIGS. 21A and 21B are cross-sectional views schematically showing a part of a method of manufacturing the magnetic memory device according to the third embodiment.

### DETAILED DESCRIPTION

In general, according to one embodiment, a magnetic memory device includes: a first wiring line extending along a first direction; a second wiring line provided on an upper layer side of the first wiring line and extending along a second direction intersecting the first direction; a memory cell provided between the first wiring line and the second wiring line, including a bottom surface connected to the first wiring line and a top surface connected to the second wiring line, and including a magnetoresistance effect element and a switching element stacked in a third direction intersecting the first and second directions; and a contact including a top surface connected to the second wiring line, the top surface of the contact being located higher than the top surface of the memory cell.

Embodiments will be described hereinafter with reference to the accompanying drawings.

### First Embodiment

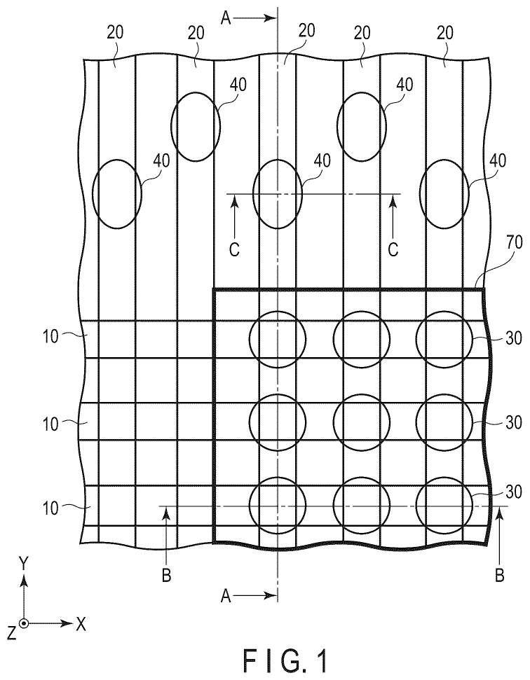

FIG. 1 is a planar pattern diagram schematically showing a configuration of a magnetic memory device according to the first embodiment as viewed from a Z direction. That is, FIG. 1 is a planar pattern diagram schematically showing a planner pattern of each of structural elements included in the magnetic memory device.

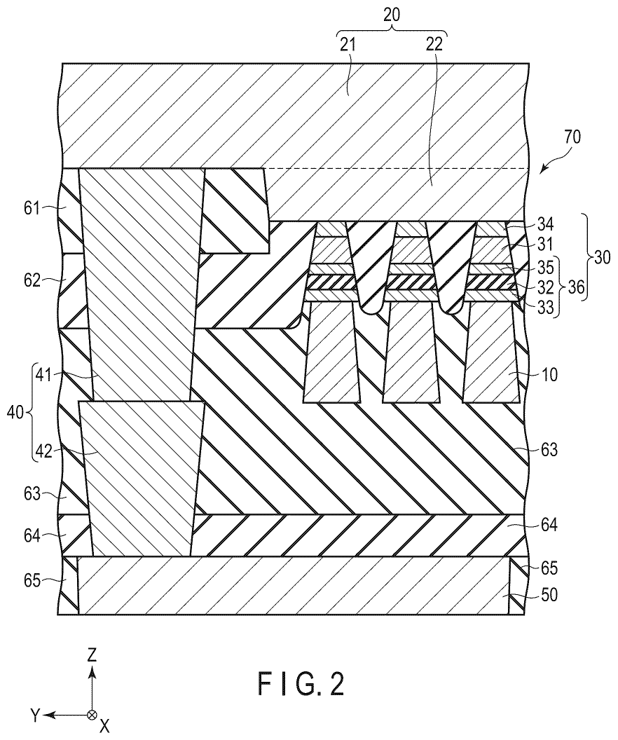

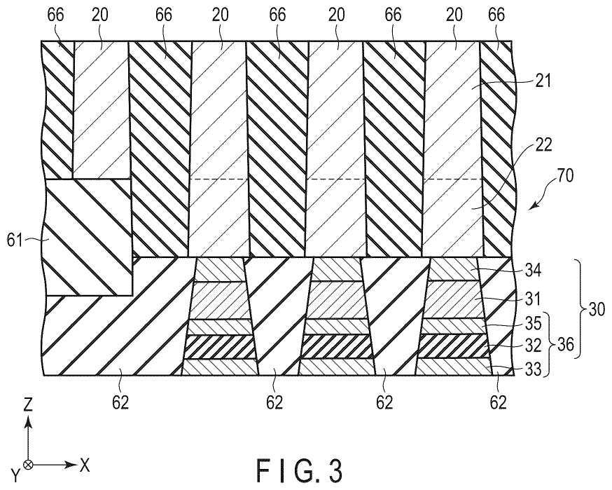

FIG. 2 is a cross-sectional view perpendicular to an X direction, schematically showing the configuration of the magnetic memory device of this embodiment, and corresponds to a cross-sectional view taken along line A-A in FIG. 1. FIG. 3 is a cross-sectional view perpendicular to a Y direction, schematically showing the configuration of the magnetic memory device of this embodiment, and corresponds to a cross-sectional view taken along line B-B in FIG. 1. FIG. 4 is a cross-sectional view perpendicular to the Y direction, schematically showing the configuration of the magnetic memory device of this embodiment, and corresponds to a cross-sectional view taken along line C-C in FIG. 1. Note that in FIGS. 3 and 4, the illustration of the region below the memory cell 30 is omitted, but in reality, word lines 10 and the like are provided as in the case of FIG. 2.

Here, the X direction, Y direction, and Z direction intersect each other. More specifically, the X, Y, and Z directions are orthogonal to each other.

The magnetic memory device of this embodiment includes a plurality of word lines (first wiring lines) 10, a plurality of bit lines (second wiring lines) 20, a plurality of memory cells 30, a plurality of contacts 40, a plurality of lower wiring lines 50, and a plurality of insulating layers 61 to 66. Each of the above-mentioned components is provided on a semiconductor substrate, which is not shown in the figure.

The plurality of word lines 10 are arranged along the Y direction at the same pitch and each extend along the X direction.

The plurality of bit lines 20 are provided on an upper layer side of the word lines 10 and are arranged along the X direction at the same pitch, each extending along the Y direction.

The plurality of memory cells 30 are arranged along the X direction and the Y direction. Each memory cell 30 is provided between the corresponding word line 10 and the corresponding bit line 20 and has a bottom surface connected to the word line 10 and a top surface connected to the bit line 20.

Each memory cell 30 includes a magnetoresistance effect element 31, a selector material layer (switching material layer) 32, a bottom electrode 33, a top electrode 34, and a middle electrode 35. These components are stacked along the Z direction. The selector (switching element) 36 is substantially constituted by the selector material layer 32, the bottom electrode 33, and the middle electrode 35, and the magnetoresistance effect element 31 is stacked on an upper layer side of the selector 36.

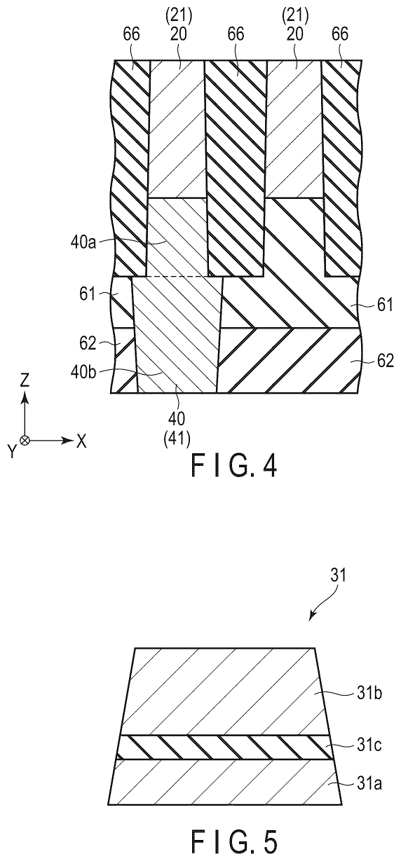

FIG. 5 is a cross-sectional view schematically showing a basic configuration of the magnetoresistance effect element 31.

The magnetoresistance effect element 31 is a magnetic tunnel junction (MTJ) element, and includes a storage layer (first magnetic layer) 31a, a reference layer (second magnetic layer) 31b, and a tunnel barrier layer (nonmagnetic layer) 31c. The element has such a configuration that the storage layer 31a, the reference layer 31b, and the tunnel barrier layer 31c are stacked one on another along the Z direction.

The storage layer 31a is a ferromagnetic layer having a variable magnetization direction. Here, the variable magnetization direction means that the magnetization direction changes for a given write current. The reference layer 31b is a ferromagnetic layer having a fixed magnetization direction. The fixed magnetization direction means that the magnetization direction does not change for a given write current. The tunnel barrier layer 31c is an insulating layer provided between the storage layer 31a and the reference layer 31b.

When the magnetization direction of the storage layer 31a is parallel to the magnetization direction of the reference layer 31b, the magnetoresistance effect element 31 exhibits a low-resistance state having a relatively low resistance. When the magnetization direction of the storage layer 31a is antiparallel to the magnetization direction of the reference layer 31b, the magnetoresistance effect element 31 exhibits a high-resistance state having a relatively high resistance. With these characteristics, the magnetoresistance effect element 31 can store binary data according to its resistance state.

Note that the example shown in FIG. 5 illustrates a bottom-free type magnetoresistance effect element in which the storage layer 31a is located on a lower side of the reference layer 31b. But, a top-free type magnetoresistance effect element may as well be used, in which the storage layer 31a is located on an upper side of the reference layer 31b.

The selector 36 is a two-terminal type switching element and is constituted by a selector material layer 32, a bottom electrode 33, and a middle electrode 35. The selector material layer 32 is formed, for example, of silicon oxide doped with arsenic (As) or the like. The selector 36 has a characteristic of transitioning from an off state to an on state when the voltage applied between the two terminals is higher than or equal to a threshold voltage. In FIGS. 2 and 3, when the voltage applied between the bottom electrode 33 and the middle electrode 35 becomes equal to or exceeds the threshold voltage, the resistance value of the selector material layer 32 decreases significantly and the selector 36 changes from the off state to the on state.

When a voltage is applied between the word line 10 and the bit line 20 and the voltage applied to the selector 36 becomes equal to or higher than the threshold voltage, the selector 36 changes from the off state to the on state. As a result, a current flows to the magnetoresistance effect element 31 connected in series to the selector 36, thus making it possible to perform write or read with respect to the magnetoresistance effect element 31.

The contacts 40 each function as a contact electrode to the respective bit line 20, and is formed of a metal material such as tungsten (W). Each contact includes a first contact portion 41 and a second contact portion 42. The contacts 40 each have a top surface connected to the respective bit line 20, and the top surface of the contact 40 is located higher than the top surface of the memory cell 30. The bottom surface of each contact 40 is connected to the respective lower wiring line 50. With this configuration, signals are transmitted between the memory cell 30 and the lower wiring line 50 via the bit line 20 and the contact 40. Note that for the contacts 40, molybdenum (Mo) or copper (Cu) may be used.

The maximum width of the contacts 40 along the X direction is greater than the maximum width of the bit lines 20 along the X direction. In a strict sense, the maximum width of the contacts 40 is greater than the maximum width of the bit line 20 along a direction perpendicular to the direction of extension of the bit lines 20 (that is, the Y direction). Therefore, as viewed from the Z direction, a part of the pattern of the contact 40 is located on an outer side of the pattern of the respective bit line 20.

Further, as shown in FIG. 4, the contact 40 (in the example shown in the figure, the first contact portion 41) includes an upper portion 40a having a top surface connected to the respective bit line 20 and a lower portion 40b located on the lower side of the upper portion 40a. As viewed from the Y direction, the side surface of the upper portion 40a of the contact 40 is aligned with the side surface of the respective bit line 20. At the boundary between the upper portion 40a of the contact 40 and the lower portion 40b of the contact 40, the width of the upper portion 40a along the X direction (in a strict sense, the width along a direction perpendicular to the Y direction) is less than the width of the lower portion 40b along the X direction (in a strict sense, the width along a direction perpendicular to the Y direction). With this configuration, a step is created in the boundary region between the upper portion 40a and the lower portion 40b.

As already mentioned, the top surface of the contact 40 is located higher than the top surface of the memory cell 30. More specifically, a recess 70 is provided in the region where the plurality of memory cells 30 are arranged, and a part of the bottom surface of the recess 70 corresponds to the top surface of the memory cell 30. Here, the bit line 20 is connected to the top surface of the memory cell 30 and the top surface of the contact 40, thus, the thickness of the bit line 20 at the location where it is connected to the top surface of the memory cell 30 is greater than the thickness of the bit line 20 at the location where it is connected to the top surface of the contact 40.

As described above, when considered in terms of the thickness direction of the bit line 20 (the height direction, or the Z direction), the bit line 20 includes an upper portion 21 and a lower portion 22. The upper portion 21 is provided over the entire bit line 20 along its extending direction (Y direction), whereas the lower portion 22 is provided within the recess 70. In other words, the upper portion 21 of the bit line 20 is located between a first plane including the connection surface between the contact 40 and the bit line 20 and the top surface of the bit line 20, and the lower portion 22 of the bit line 20 is located between a second plane including the connection surface between the memory cell 30 and the bit line 20 and the first plane. In this embodiment, the upper portion 21 and the lower portion 22 of the bit line 20 are formed by a common patterning process. Therefore, as viewed from the Y direction, a pair of side surfaces of the lower portion 22 of the bit line 20 are aligned with a pair of side surfaces of the upper portion 21 of the bit line 20, respectively.

In this embodiment, the upper portion 21 and the lower portion 22 of the bit line 20 are formed of the same conductive material. More specifically, both the upper portion 21 and the lower portion 22 of the bit line 20 are formed of a metal material such as tungsten (W). In place of tungsten, molybdenum (Mo) or copper (Cu) may be used. Further, a metal material such as tungsten, molybdenum or copper can be used for the word lines 10 as well.

The insulating layers 61 to 66 function as interlayer insulating layers and the like. For example, the insulating layers 61, 63, 65 and 66 are formed of silicon oxide, and the insulating layers 62 and 64 are formed of silicon nitride.

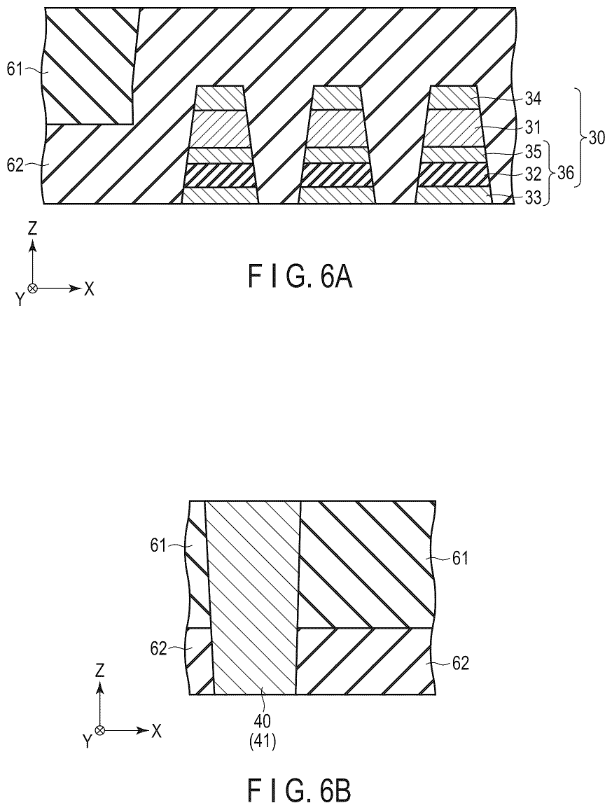

Next, a method of manufacturing the magnetic memory device of the embodiment will be described with reference to the cross-sectional views shown in FIGS. 6A and 6B to 8A and 8B, and FIGS. 1 to 4. FIGS. 6A to 8A are cross-sectional views at positions corresponding to those shown in FIG. 3, and FIGS. 6B to 8B are cross-sectional views at positions corresponding to those shown in FIG. 4.

First, as shown in FIGS. 6A and 6B, a configuration including memory cells 30, contacts 40, an insulating layer 61, an insulating layer 62 and the like is formed on a lower structure (not shown) including a semiconductor substrate. The top surface of the configuration shown in FIGS. 6A and 6B is planarized, and the top surfaces of the contacts 40 are exposed.

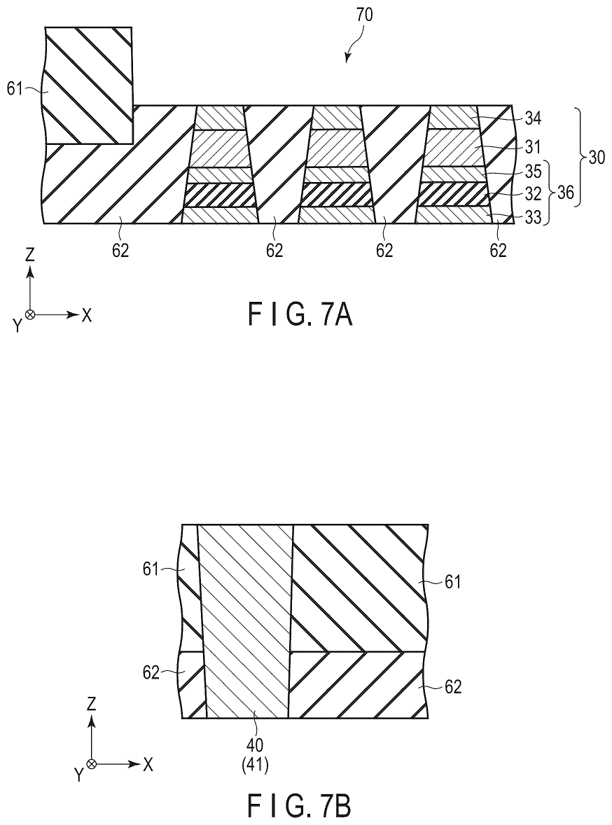

Next, as shown in FIGS. 7A and 7B, the insulating layer 62 is partially etched. Thus, a recess 70 is formed in the region where the plurality of memory cells 30 are arranged, and the top surfaces of the memory cells 30 (the top surfaces of the top electrodes 34) are exposed. The insulating layer 61 and the insulating layer 62 are formed of materials different from each other, respectively. For example, the insulating layer 61 is formed of silicon oxide and the insulating layer 62 is formed of silicon nitride. With this configuration, the recess 70 can be formed by selectively etching the insulating layer 62 against the insulating layer 61.

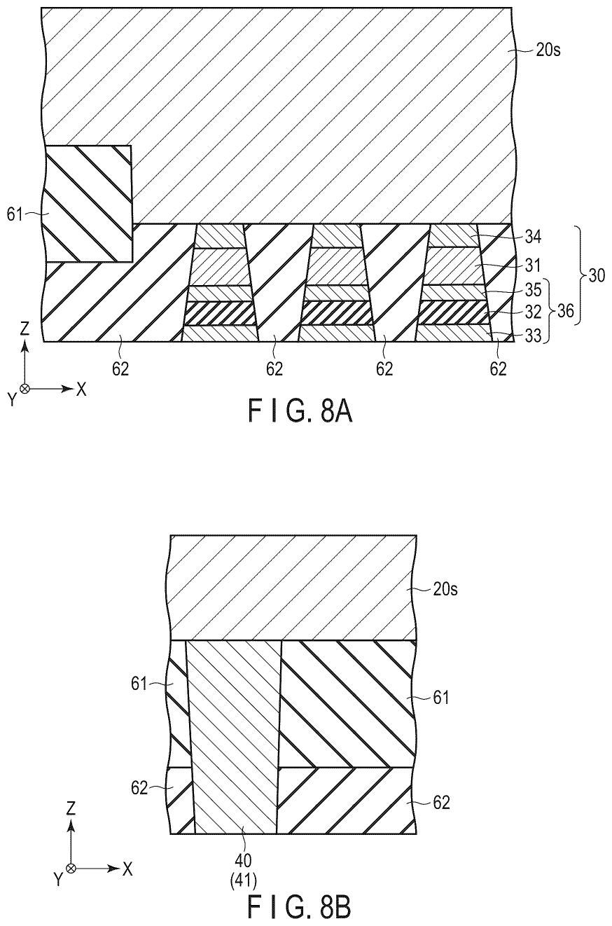

Next, as shown in FIG. 8A and FIG. 8B, a metal layer (for example, a tungsten layer) is formed as the conductive layer 20s for the bit lines 20 on the configuration obtained in the processing step shown in FIGS. 7A and 7B. More specifically, after forming the conductive layer 20s on the entire surface, planarization is carried out by chemical mechanical polishing (CMP), and thus a conductive layer 20s with a planarized top surface is obtained.

After that, as shown in FIGS. 3 and 4, the material of the conductive layer 20s is selectively etched to pattern the conductive layer 20s into a line shape, and thus a plurality of bit lines 20 are formed. In the region where the memory cells 30 are provided (the region where the recess 70 is provided), the thickness of the conductive layer 20s is greater as compared to that of the region where the contacts 40 are provided. Further, the conductive layer 20s is patterned so that the width of the bit lines 20 is less than the width of the contacts 40 as viewed from the Y direction. Moreover, the bit lines 20 and the contacts 40 are formed of the same conductive material (a metallic material such as tungsten). Thus, the upper portions 40a of the contacts 40 as well are partially etched, the side surface of the upper portion 40a of each contact 40 is aligned with the side surface of the respective bit line 20, and the width of the upper portion 40a of each contact 40 is less than the width of the lower portion 40b of the respective contact 40.

Furthermore, by forming the insulating layer 66, a magnetic memory device having such a configuration as shown in FIGS. 1 to 4 can be obtained.

As described above, in this embodiment, the top surfaces of the contacts 40 are located higher than the top surfaces of the memory cells 30. With this configuration, it is possible to obtain a magnetic memory device having excellent characteristics and reliability, as described below.

As already mentioned, the width of contacts 40 is greater than the width of the bit lines 20, and therefore it is important to ensure isolation between the contacts 40 and the respective bit lines 20 adjacent to the contacts 40. In order to achieve this, it is preferable to reduce the width of the upper portions 40a of the contacts 40 by carry out over-etching when forming the pattern of the bit line 20 by etching.

On the other hand, when over-etching is excessively performed in the locations where the memory cells 30 are provided, etching damage may be caused to the memory cells 30, which may adversely affect the characteristics and reliability of the memory cells 30. In particular, when the magnetoresistance effect element 31 is stacked on the upper layer side of the selector 36, the characteristics and reliability of the magnetoresistance effect element 31 may be significantly degraded.

In this embodiment, the top surfaces of the contacts 40 are located higher than the top surfaces of the memory cells 30. In other words, the top surfaces of the memory cells 30 are located lower than the top surfaces of the contacts 40. With this configuration, even if the conductive layer 20s for the bit lines 20 is sufficiently over-etched in the region where the contacts 40 are provided, the amount of over-etching of the conductive layer 20s can be precisely suppressed in the region where the memory cells 30 are provided.

Therefore, according to this embodiment, the etching of the conductive layer 20s for bit lines 20 can be accurately carried out in both the regions where the contacts 40 are provided and where the memory cells 30 are provided, thereby making it possible to obtain a magnetic memory device with excellent characteristics and reliability.

### Second Embodiment

Next, a magnetic memory device according to the second embodiment will be described. Note that the basic items are similar to those of the first embodiment, and therefore the explanation of the items described in the first embodiment will be omitted.

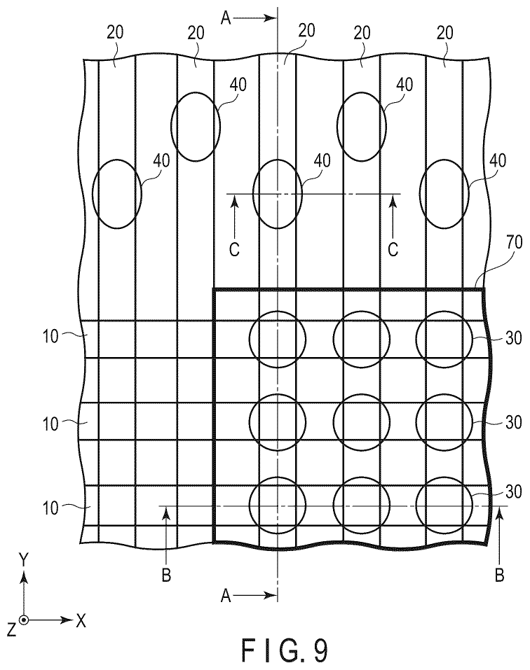

FIG. 9 is a planar pattern diagram schematically showing a configuration of the magnetic memory device of this embodiment as viewed from the Z direction.

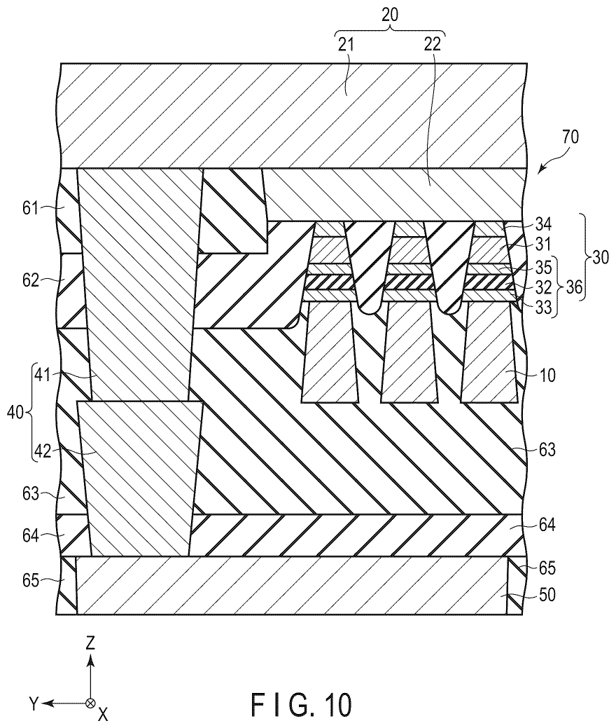

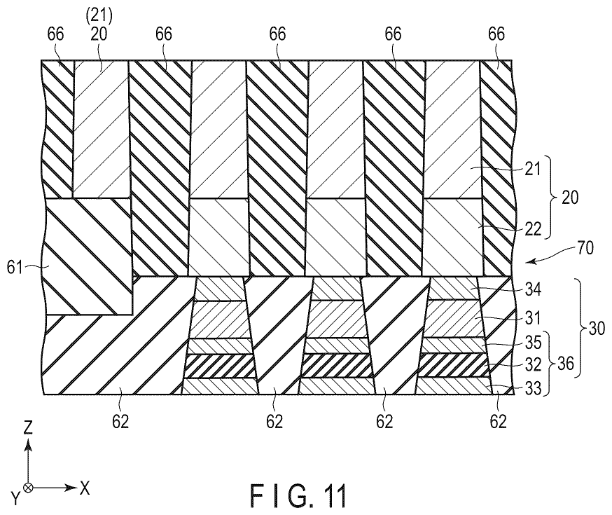

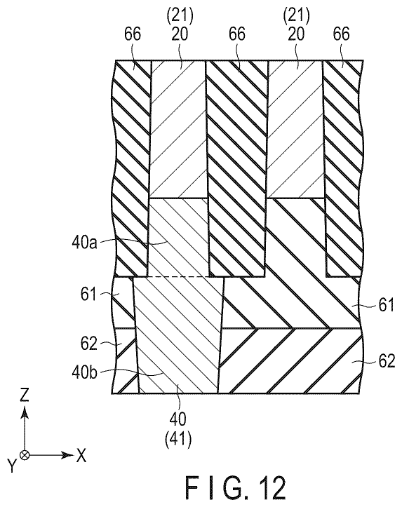

FIG. 10 is a cross-sectional view perpendicular to the X direction schematically showing the configuration of the magnetic memory device of this embodiment, and it corresponds to a cross-section taken along line A-A in FIG. 9. FIG. 11 is a cross-sectional view perpendicular to the Y direction schematically showing the configuration of the magnetic memory device, and it corresponds to a cross-section taken along line B-B of FIG. 9. FIG. 12 is a cross-sectional view perpendicular to the Y direction schematically showing the configuration of the magnetic memory device of this embodiment, and it corresponds to a cross-section taken along line C-C of FIG. 9. In FIGS. 11 and 12, the region below the memory cells 30 is omitted from illustration, but in reality, word lines 10 and the like are provided as in the case shown in FIG. 10.

In the first embodiment, the upper portions 21 and the lower portions 22 of the bit lines 20 are formed from the same conductive material, whereas in this embodiment, the upper portions 21 and the lower portions 22 of the bit lines 20 are formed from different conductive materials, respectively. More specifically, in this embodiment, the upper portions 21 of the bit lines 20 are formed of a metal material such as tungsten (W), as in the first embodiment. The lower portions 22 of the bit lines 20 are formed of a conductive material containing carbon (C), ruthenium (Ru) or silicon (Si). More specifically, the lower portions 22 of the bit lines 20 are formed of a conductive material containing carbon as a major component, a conductive material containing ruthenium as a major component, or a conductive material containing silicon as a major component. In this embodiment, the lower portions 22 of the bit lines 20 are formed of a conductive material containing substantially only carbon.

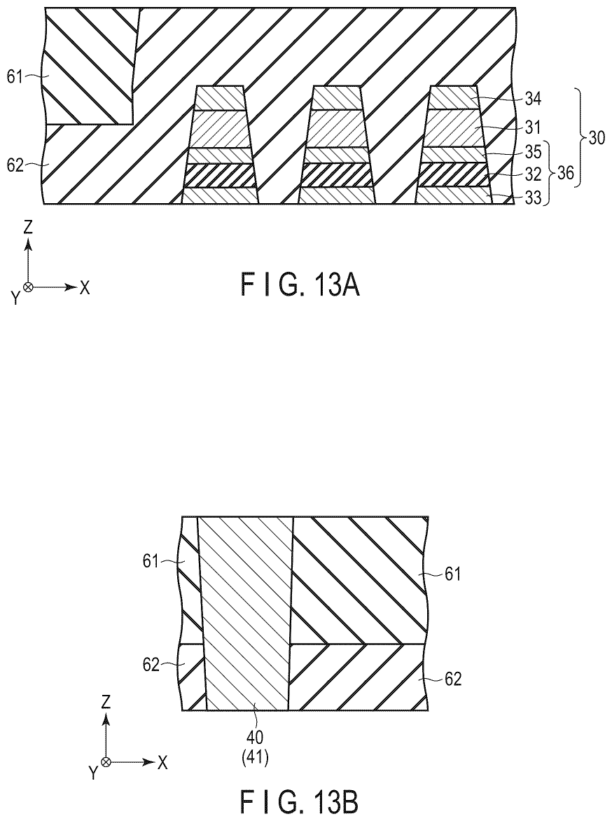

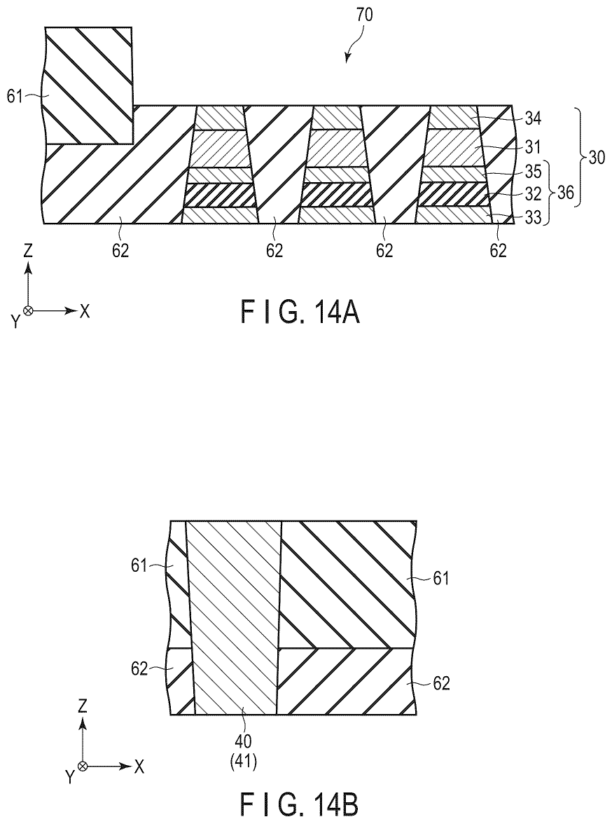

Next, a method of manufacturing the magnetic memory device of this embodiment will be described with reference to cross-sectional views shown in FIGS. 13A and 13B to 18A and 18B, and FIGS. 9 to 12. FIGS. 13A to 18A are cross-sectional views at locations corresponding to those indicated in FIG. 11, and FIGS. 13B to 18B are cross-sectional views at locations corresponding to those indicated in FIG. 12.

The processing step shown in FIGS. 13A and 13B and that shown in FIGS. 14A and 14B are the same as the processing steps shown in FIGS. 6A and 6B and that shown in FIGS. 7A and 7B of the first embodiment, respectively, and as shown in FIGS. 14A and 14B, a recess 70 is formed in the region where a plurality of memory cells 30 are arranged.

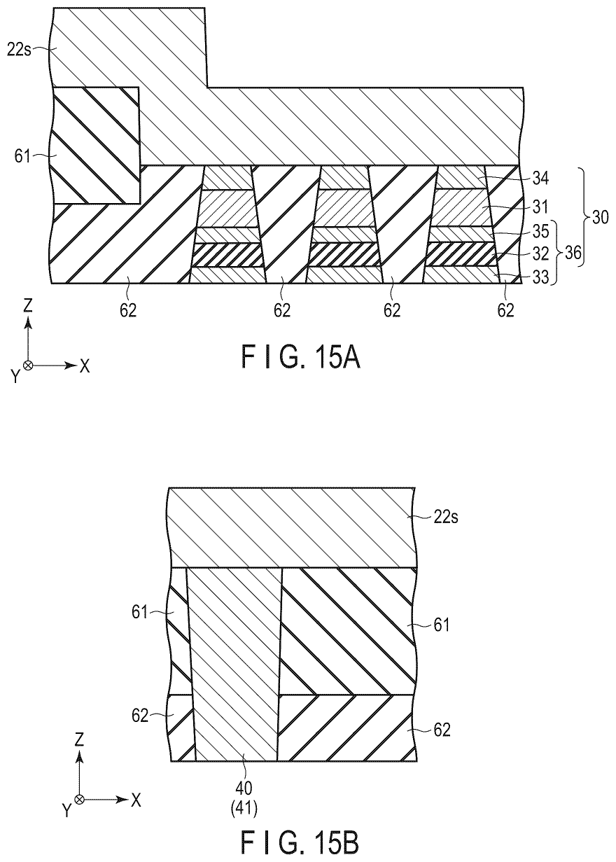

Next, as shown in FIGS. 15A and 15B, a carbon layer is formed as a conductive layer 22s for the lower portions 22 of the bit lines 20 on the configuration obtained in the step shown in FIGS. 14A and 14B.

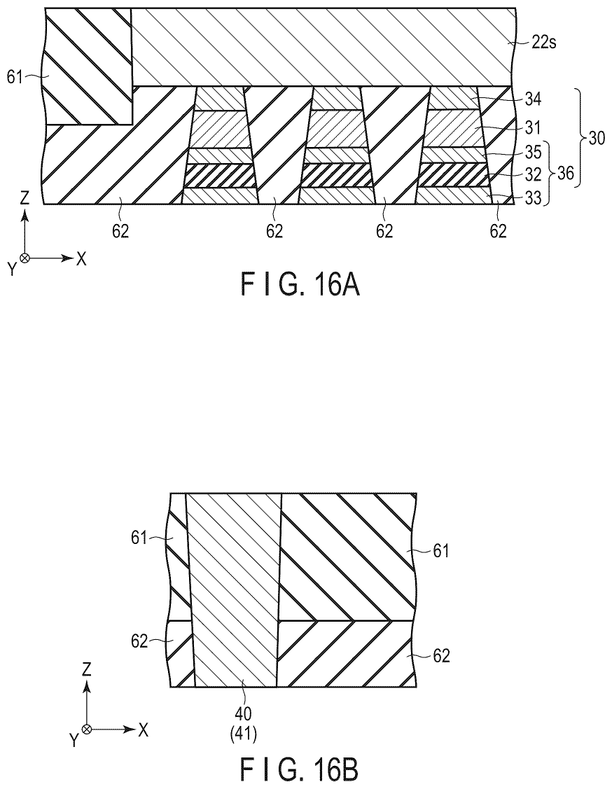

Subsequently, as shown in FIGS. 16A and 16B, a planarization process is carried out by CMP to planarize the top surface of the conductive layer 22s. With the planarization process, the conductive layer 22s remains only in the recess 70.

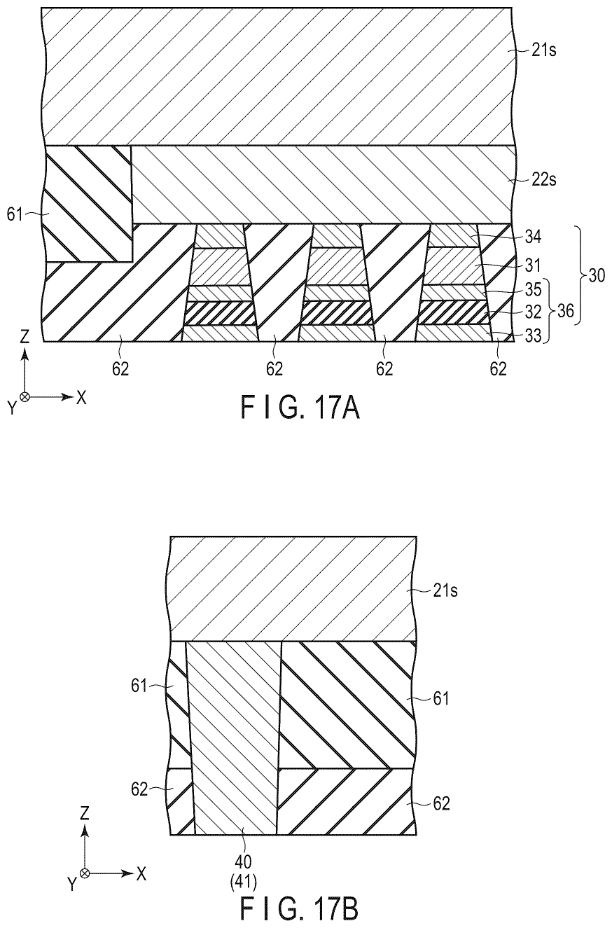

Next, as shown in FIGS. 17A and 17B, a metal layer (for example, tungsten layer) is formed as the conductive layer 21s for the upper portions 21 of the bit lines 20 on the configuration obtained in the processing step shown in FIGS. 16A and 16B.

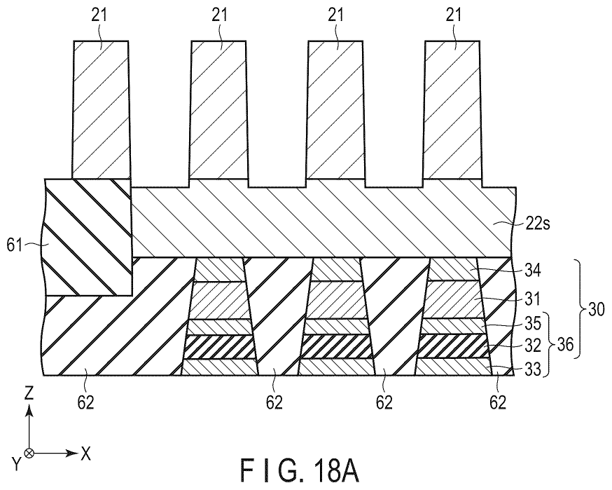

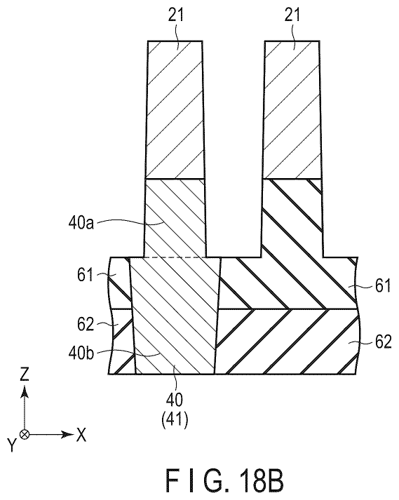

Next, as shown in FIGS. 18A and 18B, the material of the conductive layer 21s is selectively etched and thus the conductive layer 21s is patterned into lines. In this manner, the upper portions 21 of the bit lines 20 are formed. At this time, etching is performed under conditions where the etching rate of the conductive layer 21s is sufficiently higher than the etching rate of the conductive layer 22s. With this operation, in the region where the memory cells 30 are provided (the region where the recess 70 is provided), the conductive layer 22s functions as an etching stopper and the conductive layer 21s is selectively etched while the conductive layer 22s is not substantially etched.

On the other hand, in the region where the contacts 40 are provided, as described in the first embodiment, the conductive layer 21s is patterned so that the width of the bit lines 20 is less than the width of the contacts 40 as viewed from the Y direction. Here, note that the upper portions 21 of the bit lines 20 and the contacts 40 are formed from the same metal material (for example, tungsten). With this configuration, a part of the upper portion 40a of each contact 40 is etched as well, and thus the side surface of the upper portion 40a of each contact 40 is aligned with the side surface of the upper portion 21 of the respective bit line 20, and the width of the upper portion 40a of each contact 40 is less than that of the lower portion 40b of the respective contact 40. After that, as shown in FIGS. 11 and 12, the material of the conductive layer 22s is selectively etched and thus the lower portions 22 of the plurality of bit lines 20 are formed. At this time, the upper portions 21 of the bit lines 20 functions as an etching mask, and therefore a pair of side surfaces of the lower portion 22 of each bit line 20 are aligned respectively with a pair of side surfaces of the upper portion 21 of the corresponding bit line 20 as viewed from the Y direction.

Further, by forming the insulating layer 66, a magnetic memory device having the configuration shown in FIGS. 9 to 12 can be obtained.

As described above, the basic configuration of this embodiment is similar to that of the first embodiment, and advantageous effects similar to those of the first embodiment can be obtained in this embodiment as well. Further, in this embodiment, the conductive material of the lower portions 22 of the bit lines 20 is different from the conductive material of the upper portions 21 of the bit lines 20, and the conductive layer 22s of the lower portions 22 of the bit lines 20 functions as an etching stopper when forming the pattern of the upper portion 21 of the bit lines 20. Therefore, it is possible to more precisely suppress over-etching of the bit lines 20 in the region where the memory cells 30 are provided.

### Third Embodiment

Next, a magnetic memory device according to the third embodiment will be described. The basic items are similar to those of the first and second embodiments, and the description of the items already described in the first and second embodiments will be omitted.

The planar pattern diagram of the magnetic memory device according to this embodiment as viewed from the Z direction is similar to the planar pattern diagram shown in FIG. 9 of the second embodiment. Further, the cross-sectional view of the magnetic memory device of this embodiment perpendicular to the X direction (corresponding to the cross-sectional view taken along line A-A in FIG. 9) is similar to the cross-sectional view shown in FIG. 10 of the second embodiment.

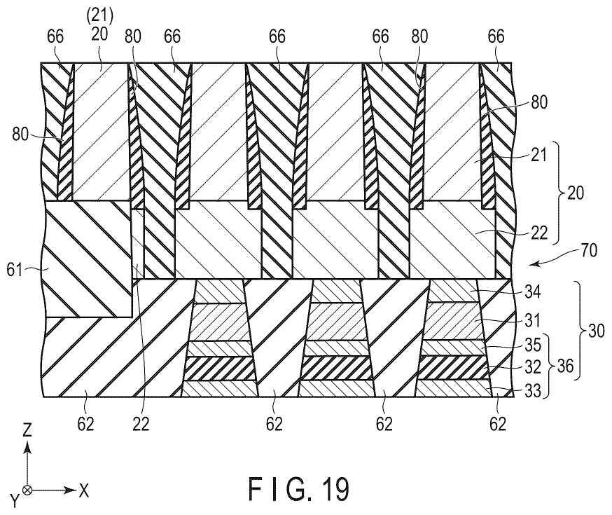

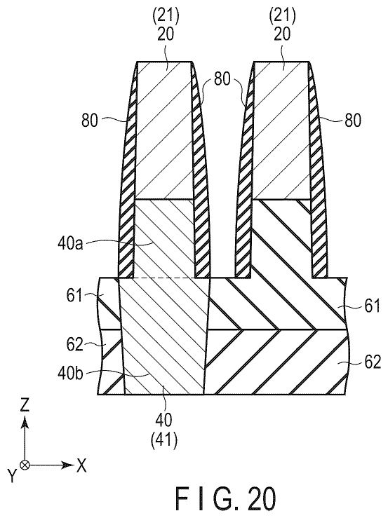

FIG. 19 is a cross-sectional view perpendicular to the Y direction, showing the magnetic memory device of this embodiment, and it corresponds to a cross-section taken along line B-B of FIG. 9. FIG. 20 is a cross-sectional view of the magnetic memory device perpendicular to the Y direction, and it corresponds to a cross-section taken along line C-C of FIG. 9. Note that in FIGS. 19 and 20, the region below the memory cells 30 is omitted from illustration, but in reality, the word lines 10 and the like are provided as in the case shown in FIG. 10.

In this embodiment as well, the upper portions 21 and the lower portions 22 of the bit lines 20 are formed of different conductive materials as in the case of the second embodiment. The conductive material of the upper portions 21 and the conductive material of the lower portions 22 are similar to those respectively used in the second embodiment.

In this embodiment, a pair of sidewall layers 80 are provided along a pair of side surfaces of the upper portion 21 of the respective bit line 20. As viewed from the Y direction, a pair of side surfaces of the lower portion 22 of each bit line 20 are aligned with a pair of side surfaces of the respective pair of sidewall layers 80. The pair of sidewall layers 80 are formed, for example, of an insulating material such as silicon nitride.

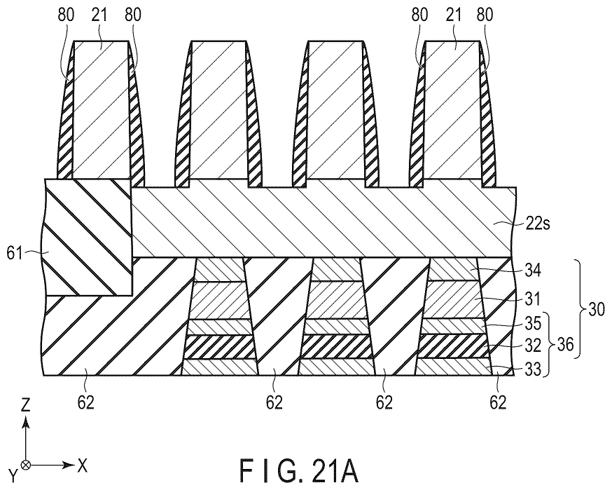

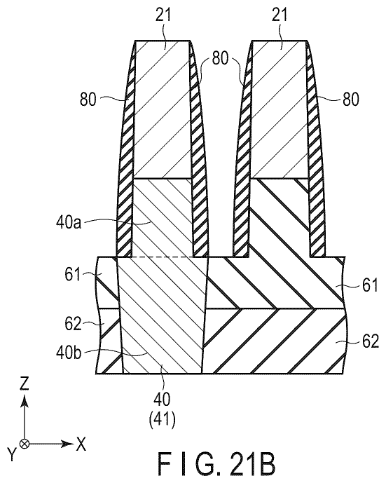

Next, a method of manufacturing the magnetic memory device will now be described with reference to the cross-sectional views shown in FIGS. 21A and 21B, as well as FIGS. 19 and 20. FIG. 21A is a cross-sectional view at a location corresponding to that shown in FIG. 19, and FIG. 21B is a cross-sectional view at a location corresponding to that shown in FIG. 20.

First, processing steps similar to those shown in FIGS. 13A and 13B to 18A and 18B of the second embodiment are carried out, and thus a configuration shown in FIGS. 18A and 18B is formed.

Next, as shown in FIGS. 21A and 21B, a pair of sidewall layers 80 are formed respectively along a pair of side surfaces of the upper portion 21 of each bit line 20. More specifically, an insulating layer for the sidewall layers 80 is formed on the configuration obtained in the process step shown in FIGS. 18A and 18B, and the insulating layer thus formed is etched by anisotropic etching such as reactive ion etching (RIE), and thus a pair of sidewall layers 80 are formed along a pair of side surfaces of the upper portion 21 of the respective bit line 20. Note that in the region where the contacts 40 are provided, the sidewall layers 80 are formed on the side surfaces of the upper portions 40a of the contacts 40, and the like, as well.

After that, as shown in FIGS. 19 and 20, the material of the conductive layer 22s is selectively etched, and thus the lower portions 22 of the plurality of bit lines 20 are formed. At this time, the upper portions 21 of the bit lines 20 and the pair of sidewall layers 80 function as etching masks. With this configuration, as viewed from the Y direction, a pair of side surfaces of the lower portions 22 of the each bit line 20 are aligned with a pair of side surfaces of the respective pair of sidewall layers 80.

Furthermore, by forming the insulating layer 66, a magnetic memory device having the configuration shown in FIGS. 9, 10, 19, and 20 can be obtained.

As described above, the basic configuration of this embodiment as well is similar to those of the first and second embodiments, and advantageous effects similar to those of the first and second embodiments can be obtained in this embodiment as well. In addition, according to this embodiment, when etching the conductive layer 22s to form the lower portion 22 of each bit line 20, a pair of sidewall layers 80 can protect a pair of side surfaces of the upper portion 21 of the respective bit line 20. For example, when carbon is used as the material of the conductive layer 22s, the conductive layer 22s is etched using oxygen gas. In such a case, with the sidewall layers 80 thus provided, it is possible to prevent the upper portions 21 of the bit lines 20 from being oxidized.

Note here that in each of the first to third embodiments described above, the magnetoresistance effect element 31 is stacked on the upper layer side of the selector 36, but the selector 36 may as well be stacked on the upper layer side of the magnetoresistance effect element 31.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A magnetic memory device comprising:
a first wiring line extending along a first direction;
a second wiring line provided on an upper layer side of the first wiring line and extending along a second direction intersecting the first direction;
a memory cell provided between the first wiring line and the second wiring line, including a bottom surface connected to the first wiring line and a top surface connected to the second wiring line, and including a magnetoresistance effect element and a switching element stacked in a third direction intersecting the first and second directions; and
a contact including a top surface connected to the second wiring line, the top surface of the contact being located higher than the top surface of the memory cell.

2. The device of claim 1, wherein
a thickness of the second wiring line at a location where the second wiring line is connected to the top surface of the memory cell is greater than a thickness of the second wiring line at a location where the second wiring line is connected to the top surface of the contact.

3. The device of claim 1, wherein
a maximum width of the contact along a direction perpendicular to the second direction is greater than a maximum width of the second wiring line along a direction perpendicular to the second direction.

4. The device of claim 1, wherein
the contact includes an upper portion including a side surface aligned with a side surface of the second wiring line as viewed from the second direction and a lower portion located on a lower side of the upper portion, and
in a boundary between the upper portion of the contact and the lower portion of the contact, a width of the upper portion of the contact along a direction perpendicular to the second direction is less than a width of the lower portion of the contact along a direction perpendicular to the second direction.

5. The device of claim 1, wherein
the second wiring line includes an upper portion located between a first plane including a connection surface between the contact and the second wiring line and a top surface of the second wiring line, and a lower portion located between a second plane including a connection surface between the memory cell and the second wiring line and the first plane.

6. The device of claim 5, wherein
a pair of side surfaces of the lower portion of the second wiring line are aligned with a pair of side surfaces of the upper portion of the second wiring line as viewed from the second direction.

7. The device of claim 5, wherein
the upper portion of the second wiring line is formed of a metal material.

8. The device of claim 5, wherein
the upper portion of the second wiring line and the lower portion of the second wiring line are formed of a same conductive material.

9. The device of claim 5, wherein
the upper portion of the second wiring line and the lower portion of the second wiring line are formed of different conductive materials.

10. The device of claim 9, wherein
the lower portion of the second wiring line is formed of a conductive material containing carbon, ruthenium or silicon.

11. The device of claim 9, further comprising:
a pair of sidewall layers provided along a pair of side surfaces of the upper portion of the second wiring line.

12. The device of claim 11, wherein
as viewed from the second direction, a pair of side surfaces of the lower portion of the second wiring line are aligned with a pair of side surfaces of the pair of sidewall layers.

13. The device of claim 1, wherein
the magnetoresistance effect element is stacked on an upper layer side of the switching element.

14. The device of claim 1, wherein
the magnetoresistance effect element includes a first magnetic layer having a variable magnetization direction, a second magnetic layer having a fixed magnetization direction, and a nonmagnetic layer provided between the first magnetic layer and the second magnetic layer.

15. The device of claim 1, wherein
the switching element is a two-terminal type switching element and has a characteristic of changing from an off state to an on state when a voltage applied between two terminals thereof is higher than or equal to a threshold voltage.
